(19) United States
(12) Patent Application Publication
(10) Pub. No.: US 2018/0108870 A1
(43) Pub. Date: Apr. 19, 2018

(54) ORGANIC LIGHT-EMITTING DISPLAY DEVICE

(71) Applicant: LG CHEM, LTD., Seoul (KR)

(72) Inventors: Ilha LEE, Daejeon (KR); Ji Young HWANG, Daejeon (KR); Seung Heon LEE, Daejeon (KR); Dong Hyun OH, Daejeon (KR); Ki-Hwan KIM, Daejeon (KR); Han Min SEO, Daejeon (KR); Chan Hyoung PARK, Daejeon (KR); Soon-Sung CHUNG, Daejeon (KR)

(21) Appl. No.: 15/542,745

(22) PCT Filed: May 9, 2016
(86) PCT No.: PCT/KR2016/004802

§ 371 Date: Jul. 11, 2017

(30) Foreign Application Priority Data
May 11, 2015 (KR) 10-2015-0065268

(51) Int. Cl. H01L 51/52; H01L 27/32

(52) U.S. Cl. CPC H01L 51/5281; H01L 27/3276; H01L 27/3213

(57) ABSTRACT

The present specification relates to an organic light emitting display device.

### TECHNICAL FIELD

This application claims priority to and the benefit of Korean Patent Application No. 10-2015-0065268 filed in the Korean Intellectual Property Office on May 11, 2015, the entire contents of which are incorporated herein by reference.

The present specification relates to an organic light emitting display device.

### BACKGROUND ART

As a flat panel display device, in which weight and a volume that are the disadvantages of a cathode ray tube (CRT) are decreased, an organic light emitting display device which controls the quantity of light emission of an organic light emitting layer to display an image and the like are in the spotlight.

The organic light emitting display device has a structure, in which a sub pixel driving unit array and an organic light emitting array are formed on a substrate, and an image is displayed by light emitted from an organic light emitting device of the organic light emitting array. The organic light emitting display device is a self-luminous device which uses a thin emission layer between electrodes and has an advantage in that the organic light emitting display device may become thin like paper.

In the case of the organic light emitting display device, an electrode and a wiring line of a thin film transistor of each pixel are formed of a metal, and there is a problem in that high light reflectance by the metal electrode and wiring line may disturb a screen of a display.

### DETAILED DESCRIPTION OF THE INVENTION

### Technical Problem

The present specification provides an organic light emitting display device, which is capable of implementing a display having a high image quality by controlling a glare phenomenon by a wiring electrode of the organic light emitting display device.

### Technical Solution

An exemplary embodiment of the present specification provides an organic light emitting display device, comprising: a substrate; a plurality of gate lines and a plurality of data lines which are provided on the substrate while crossing one another; a plurality of pixel areas divided by the gate lines and the data lines; a thin film transistor provided at one side of each of the pixel areas and comprising a gate electrode connected with the gate line, a semiconductor layer provided on the gate electrode while being insulated from the gate electrode, a source electrode electrically connected with the data line, and a drain electrode electrically connected with a pixel electrode or a common electrode; an organic light emitting device provided on each of the pixel areas and emitting red, green, blue or white light; and a light reflection reducing layer provided on one surface of at least one of the gate electrode, the source electrode, the drain electrode, the gate line, and the data line, in which the light reflection reducing layer satisfies 0.004 or more and 0.22 or less that is a value of Equation 1 below.

$$\frac{( k \times t )}{λ} \qquad [ Equation 1 ]$$

In Equation 1, k means an extinction coefficient of the light reflection reducing layer, t means a thickness of the light reflection reducing layer, and λ means a wavelength of light.

### Advantageous Effects

The organic light emitting display device according to the present specification may implement a display having a high image quality by controlling light reflectance by the wiring electrode.

### BRIEF DESCRIPTION OF DRAWINGS

FIG. 1 illustrates an example of one pixel area of the present specification.

FIG. 2 illustrates a cross-section of an organic light emitting display device according to an exemplary embodiment of the present specification.

FIG. 3 is a graph representing values of n and k according to a wavelength of a light reflection reducing layer in Example 1.

FIG. 4 is a graph representing values of n and k according to a wavelength of a MoTi layer in Comparative Example 1.

FIG. 5 represents a comparison of reflectance between Example 1 and Comparative Example 1.

FIG. 6 represents reflectance of Example 13.

FIG. 7 represents reflectance of Example 14.

FIGS. 8 and 9 represent values of reflectance and an optical constant implemented by a structure manufactured in Example 15.

### BEST MODE

In the present specification, when it is said that a specific member is positioned “on” the other member, this comprises a case where another member is present between two members, as well as a case where the specific member is in contact with the other member.

In the specification, when it is said that a specific part “comprises” a specific constituent element, unless explicitly described to the contrary, this means that another constituent element may be further comprised, not that another constituent element is excluded.

Hereinafter, the present specification will be described in more detail.

In the present specification, a display device is a term collectively referring to a TV, a computer monitor, or the like, and comprises a display element that forms an image, and a case that supports the display element.

A black matrix is applied to a display device in the related art in order to prevent light reflection, a light leakage phenomenon, and the like. Recently, a structure called a color filter on TFT array (COT or COA), in which a color filter is formed on an array substrate together with a thin film transistor, is introduced, so that a structure which does not use the foregoing black matrix is developed. By the introduction of the structure which does not use the black matrix, it is possible to obtain effects, such as transmissivity improvement, luminance improvement, and backlight efficiency improvement of the display device. However, in the case of the structure which does not use the black matrix, regions, in which metal electrodes comprised in the display device are exposable, are increased, so that there occurs a problem due to color and reflection characteristics of the metal electrode. Particularly, recently, the display device becomes large and resolution of the display device is increased, so that a technology of reducing reflection and color characteristics by the metal electrode comprised in the display device is required.

In this respect, the present inventors found out the fact that in a display device comprising a conductive layer, such as a metal, light reflection and diffraction characteristics by the conductive layer are major influences on visibility of the conductive layer and aimed to improve the visibility of the conductive layer.

An organic light emitting display device according to an exemplary embodiment of the present specification adopts a light reflection reducing layer on a wiring electrode, such as a gate electrode, a source electrode, a drain electrode, gate lines, and data lines, thereby greatly improving visibility degradation according to high reflectance of the wiring electrode.

Further, when the light reflection reducing layer is used, there is an advantage in that it is not necessary to form a black matrix on a region corresponding to a thin film transistor.

Particularly, since the light reflection reducing layer has a light absorbing property, the quantity of light incident to the wiring electrode and the quantity of light reflected from a pixel electrode and a common electrode are decreased, thereby decreasing light reflectance by the wiring electrode.

An exemplary embodiment of the present specification provides an organic light emitting display device, comprising: a substrate; a plurality of gate lines and a plurality of data lines which are provided on the substrate while crossing one another; a plurality of pixel areas divided by the gate lines and the data lines; a thin film transistor provided at one side of each of the pixel areas and comprising a gate electrode connected with the gate line, a semiconductor layer provided on the gate electrode while being insulated from the gate electrode, a source electrode electrically connected with the data line, and a drain electrode electrically connected with a pixel electrode or a common electrode; an organic light emitting device provided on each of the pixel areas and emitting red, green, blue or white light; and a light reflection reducing layer provided on one surface of at least one of the gate electrode, the source electrode, the drain electrode, the gate line, and the data line, in which the light reflection reducing layer satisfies 0.004 or more and 0.22 or less that is a value of Equation 1 below.

$$\frac{( k \times t )}{λ} \qquad [ Equation 1 ]$$

In Equation 1, k means an extinction coefficient of the light reflection reducing layer, t means a thickness of the light reflection reducing layer, and λ means a wavelength of light.

When external light is incident to an electrode provided with the light reflection reducing layer, there exists primary reflected light reflected from a surface of the light reflection reducing layer, and there exists secondary reflected light which pass through the light reflection reducing layer and is reflected from a surface of a lower electrode.

The light reflection reducing layer may decrease light reflectance through destructive interference between the primary reflected light and the secondary reflected light.

The present inventors found out that when the light reflection reducing layer, which satisfies 0.004 or more and 0.22 or less that is a value of Equation 1, is provided while being in contact with a wiring electrode, it is possible to implement high resolution of the display by remarkably reducing light reflectance by the wiring electrode through the destructive interference.

Particularly, a condition, under which the primary reflected light and the secondary reflected light have a phase difference of 180° and thus destructively interfere, is expressed by Equation 2 below.

$$t = \frac{λ}{4 \cdot n} \times N \qquad [ Equation 2 ]$$

In Equation 2, t means a thickness of the light reflection reducing layer, λ means a wavelength of light, n means a refractive index of the light reflection reducing layer, and N means a predetermined odd number, such as 1, 3, and 5.

Primary reflectance under the destructive interference condition may be obtained by Equation 3 below.

$${R}_{1} = [ \frac{{( n - 1 )}^{2} + {k}^{2}}{{( n + 1 )}^{2} + {k}^{2}} ] \qquad [ Equation 3 ]$$

In Equation 3, n means a refractive index of the light reflection reducing layer, and k means an extinction coefficient of the light reflection reducing layer.

Further, secondary reflectance under the destructive interference condition may be obtained by Equation 4 below.

$${R}_{2} = {R}_{metal} ( 1 - {R}_{1} ) {I}_{0} exp ( - \frac{2 π}{n} \cdot k \cdot N ) \qquad [ Equation 4 ]$$

In Equation 4, Rₘₑₜₐₗ means reflectance of a surface of the wiring electrode, R₁ means primary reflectance in the light reflection reducing layer, I₀ means intensity of incident light, n means a refractive index of the light reflection reducing layer, k means an extinction coefficient of the light reflection reducing layer, and N means a predetermined odd number, such as 1, 3, and 5.

According to the exemplary embodiment of the present specification, an absolute value of a difference between the primary reflectance and the secondary reflectance may be 0.13 or more and 0.42 or less.

According to the exemplary embodiment of the present specification, λ may be 550 nm. That is, light may have a wavelength of 550 nm.

According to the exemplary embodiment of the present specification, the gate electrode, the source electrode, the drain electrode, the gate line, and the data line may be collectively called the wiring electrode.

According to the exemplary embodiment of the present specification, the light reflection reducing layer may be provided on a surface opposite to a surface of the gate electrode, the source electrode, the drain electrode, the gate line, and the data line which is adjacent to the substrate.

According to the exemplary embodiment of the present specification, a thickness of the light reflection reducing layer may be 5 nm or more and 100 nm or less, and more preferably, 10 nm or more and 100 nm or less. Particularly, according to the exemplary embodiment of the present specification, a thickness of the light reflection reducing layer may be 20 nm or more and 60 nm or less.

When a thickness of the light reflection reducing layer is less than 10 nm, there may occur a problem in that light reflectance of the wiring electrode is not sufficiently controlled. Further, when a thickness of the light reflection reducing layer is more than 100 nm, there may occur a problem in that it is difficult to pattern the light reflection reducing layer.

According to the exemplary embodiment of the present specification, an extinction coefficient k of the light reflection reducing layer may be 0.1 or more and 2 or less in light having a wavelength of 550 nm. Particularly, according to the exemplary embodiment of the present specification, an extinction coefficient k of the light reflection reducing layer may be 0.4 or more and 2 or less in light having a wavelength of 550 nm.

When the extinction coefficient is within the range, it is possible to effectively control light reflectance of the wiring electrode, thereby further improving visibility of the organic light emitting display device.

The extinction coefficient may be measured by using the Ellipsometer measurement equipment, which is well-known in the art.

The extinction coefficient k may also be called an absorption coefficient, and may be an index defining how strong a target material absorbs light at a predetermined wavelength. Accordingly, the incident light passes through the light reflection reducing layer having the thickness t and is primarily absorbed according to the degree of the extinction coefficient k, and the light reflected by the lower electrode layer passes through the light reflection reducing layer having the thickness t again and is secondarily absorbed, and then is externally reflected. Accordingly, the values of the thickness and the absorption coefficient of the light reflection reducing layer act as the important factors influencing the entire reflectance. Accordingly, according to the exemplary embodiment of the present specification, a region, in which light reflection may be decreased within a predetermined range of the absorption coefficient k and the thickness t of the light reflection reducing layer, is represented through Equation 1.

According to the exemplary embodiment of the present specification, a refractive index n of the light reflection reducing layer may be 2 or more and 3 or less in light having a wavelength of 550 nm.

The primary reflection occurs in a material of the light reflection reducing layer having the refractive index n together with the extinction coefficient k, and in this case, the main factors determining the primary reflection are the refractive index n and the absorption coefficient k. Accordingly, the refractive index n and the absorption coefficient k are closely related to each other, and the effect may be maximized when the refractive index n and the absorption coefficient k are within the foregoing ranges.

According to the exemplary embodiment of the present specification, light reflectance of the wiring electrode provided with the light reflection reducing layer may be 50% or less, and more preferably, 40% or less.

According to the exemplary embodiment of the present specification, the light reflection reducing layer may comprise one or more kinds selected from the group consisting of a metal oxide, a metal nitride, and a metal oxynitride. Particularly, according to the exemplary embodiment of the present specification, the light reflection reducing layer may comprise one or more kinds selected from the group consisting of a metal oxide, a metal nitride, and a metal oxynitride as a main material.

According to the exemplary embodiment of the present specification, the metal oxide, the metal nitride, and the metal oxynitride may be derived from one or two or more metals selected from the group consisting of Cu, Al, Mo, Ti, Ag, Ni, Mn, Au, Cr, and Co.

According to the exemplary embodiment of the present specification, the light reflection reducing layer may comprise a material selected from the group consisting of a copper oxide, a copper nitride, and a copper oxynitride.

According to the exemplary embodiment of the present specification, the light reflection reducing layer may comprise a material selected from the group consisting of an aluminum oxide, an aluminum nitride, and an aluminum oxynitride.

According to the exemplary embodiment of the present specification, the light reflection reducing layer may comprise a copper-manganese oxide.

According to the exemplary embodiment of the present specification, the light reflection reducing layer may comprise a copper-manganese oxynitride.

According to the exemplary embodiment of the present specification, the light reflection reducing layer may comprise a copper-nickel oxide.

According to the exemplary embodiment of the present specification, the light reflection reducing layer may comprise a copper-nickel oxynitride.

According to the exemplary embodiment of the present specification, the light reflection reducing layer may comprise a molybdenum-titanium oxide.

According to the exemplary embodiment of the present specification, the light reflection reducing layer may comprise a molybdenum-titanium oxynitride.

According to the exemplary embodiment of the present specification, the light reflection reducing layer may also be formed in a single layer, and may also be formed in plural layers of two or more layers. The light reflection reducing layer may have a color in the achromatic series, but is not particularly limited thereto. In this case, the color in the achromatic series means a color that does not selectively absorb light incident to a surface of an object and appears when the light is evenly reflected and absorbed with respect to a wavelength of each component.

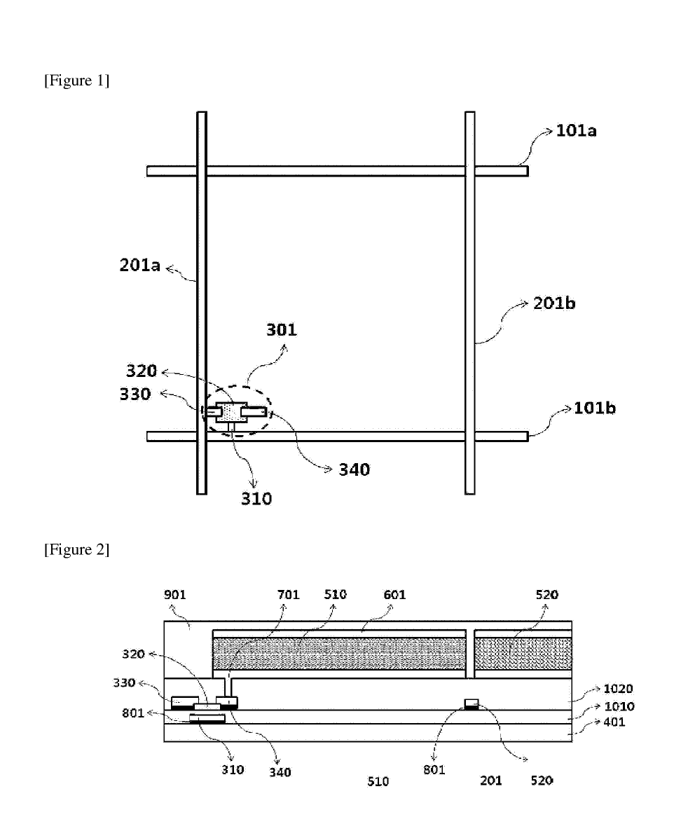

FIG. 1 illustrates an example of one pixel area of the present specification. Particularly, FIG. 1 represents a pixel area divided by a plurality of gate lines 101a and 101b and a plurality of data lines 201a and 201b provided on a substrate and a thin film transistor 301 provided within the pixel area. Further, the gate line 101b within the pixel area is connected with a gate electrode 310, the data line 201a is connected with a source electrode 330, and a drain electrode 340 is connected with a common electrode (not illustrated) or a pixel electrode (not illustrated) within the pixel area.

FIG. 2 illustrates a cross-section of an organic light emitting display device according to an exemplary embodiment of the present specification. Particularly, a thin film transistor 301 formed of the gate electrode 310, a semiconductor layer 320, the source electrode 330, and the drain electrode 340 is provided on a substrate, the pixel area is divided by the gate line (not illustrated) connected to the gate electrode and the data line 201, and organic light emitting devices, each of which comprises a first electrode 701, organic material layers 510 and 520, and a second electrode 601, are provided within the pixel area, and the respective organic light emitting devices are spaced apart from one another by a partition wall 901. Further, the gate electrode 310 and the semiconductor layer 320 may be insulated by an insulating layer 1010. The insulating layer 1010 may be a gate insulating layer. Further, in FIG. 2, each of the black layers provided on lower surfaces of the gate electrode 301, the source electrode 330, the drain electrode 340, the gate line (not illustrated), and the data line 201 means a light reflection reducing layer 801. However, the organic light emitting display device according to the exemplary embodiment of the present specification may be applied in various structures, other than the structure illustrated in FIG. 2.

According to the exemplary embodiment of the present specification, the thin film transistor comprises a gate electrode branched from the gate line and a semiconductor layer provided on the gate electrode with an insulating layer interposed therebetween. Further, the semiconductor layer is connected with a source electrode and a drain electrode with an ohmic contact layer interposed therebetween, and the source electrode is connected with the data line.

The gate line supplies a scan signal from a gate driver, and the data line supplies a video signal from a data driver.

According to the exemplary embodiment of the present specification, the gate electrode and the gate line may be provided on the substrate, and the gate insulating layer may be provided on the gate electrode and the gate line. Further, the semiconductor layer, the source electrode, the drain electrode, and the data line may be provided on the gate insulating layer.

Further, according to the exemplary embodiment of the present specification, the semiconductor layer, the source electrode, the drain electrode, and the data line may be provided on the substrate, and the gate insulating layer may be provided on the semiconductor layer, the source electrode, the drain electrode, and the data line. Further, the gate electrode and the gate line may be provided on the gate insulating layer.

Particularly, the gate insulating layer may serve to insulate the gate electrode from the semiconductor layer.

According to the exemplary embodiment of the present specification, the gate insulating layer may comprise one or more kinds selected from the group consisting of a silicon nitride (SiNx), a silicon oxide (SiO₂), an aluminum oxide (Al₂O₃), a bismuth-zinc-niobium oxide (BZM oxide), a titanium oxide, a hafnium oxide, a zirconium oxide, a tantalum oxide, and a lanthanum oxide.

According to the exemplary embodiment of the present specification, the semiconductor layer may comprise silicon and/or a silicon oxide. Particularly, the semiconductor layer may comprise amorphous silicon (Si) and/or low temperature poly silicon (LTPS).

Further, according to the exemplary embodiment of the present specification, the semiconductor layer may comprise one or more kinds selected from the group consisting of a zinc oxide (ZnO), a tin oxide (SnO), an indium oxide (InO), an indium-tin oxide (ITO), a zinc-tin oxide (ZTO), an indium-gallium-zinc oxide (IGZO), a zinc-aluminum oxide (ZAO), a molybdenum sulfide (MoS₂), and an indium-silicon-zinc oxide (ISZO).

According to the exemplary embodiment of the present specification, the gate electrode and the gate line may comprise one or more kinds selected from the group consisting of Cu, W, Mo, Al, Al—Nd, Ag, Au, Ti, TiN, Cr, Ta, and Mo—Ti. Further, the gate electrode and the gate line may have a laminate structure comprising two or more layers.

According to the exemplary embodiment of the present specification, the source electrode and the data line may comprise one or more kinds selected from the group consisting of Cu, W, Mo, Al, Al—Nd, Ag, Au, Ti, TiN, Cr, Ta, and Mo—Ti. Further, the source electrode and the data line may have a laminate structure comprising two or more layers.

According to the exemplary embodiment of the present specification, the drain electrode may comprise one or more kinds selected from the group consisting of Cu, W, Mo, Al, Al—Nd, Ag, Au, Ti, TiN, Cr, Ta, and Mo—Ti. Further, the drain electrode may have a laminate structure comprising two or more layers.

According to the exemplary embodiment of the present specification, the first electrode may be a transparent electrode. According to the exemplary embodiment of the present specification, the first electrode may be a pixel electrode. Further, according to the exemplary embodiment of the present specification, the second electrode may be a common electrode corresponding to the pixel electrode.

According to the exemplary embodiment of the present specification, the organic material layer may comprise at least one emission layer, and may further comprise one or two or more kinds selected from the group consisting of a hole injection layer, a hole transport layer, a hole blocking layer, a charge generating layer, an electron blocking layer, an electron transport layer, and an electron injection layer.

The charge generating layer refers to a layer, in which holes and electrons are generated when a voltage is applied.

According to the exemplary embodiment of the present specification, the first electrode may be an anode and the second electrode may be a cathode. Further, the first electrode may be a cathode and the second electrode may be an anode.

A material having a high work function so as to facilitate the injection of holes into the organic material layer is generally preferable as the anode. Particular examples of the anode material that may be used in the present invention comprise: a metal, such as vanadium, chrome, copper, zinc, and gold or an alloy thereof; a metal oxide, such as a zinc oxide, an indium oxide, an indium tin oxide (ITO), and an indium zinc oxide (IZO); a combination of a metal and an oxide, such as ZnO:Al or SnO₂:Sb; and a conductive polymer, such as poly(3-methylthiophene), poly[3,4-(ethylene-1,2-dioxy)thiophene](PEDT), polypyrole, and polyaniline, but the anode material is not limited thereto.

The material of the anode is not limited only to the anode, and may be used as a material of the cathode.

A material having a low work function so as to facilitate the injection of electrons into the organic material layer is preferable as a material of the cathode. Particular examples of the cathode material comprise a metal, such as magnesium, calcium, sodium, potassium, titanium, indium, yttrium, lithium, gadolinium, aluminum, silver, tin and lead, or an alloy thereof, a multi-layer structured material, such as LiF/Al or LiO₂/Al, but the cathode material is not limited thereto.

The material of the cathode is not limited only to the cathode, and may be used as a material of the anode.

A material, which is capable of receiving holes from the anode or the hole injection layer and transferring the received holes to an emission layer, and has high mobility for holes, is suitable as a material of the hole transport layer according to the present specification. Particular examples of the material of the hole transport layer comprise an arylamine-based organic material, a conductive polymer, a block copolymer having both a conjugated portion and a non-conjugated portion, and the like, but the material of the hole transport layer is not limited thereto.

A material, which is capable of emitting light in a visible light region by receiving holes and electrons from the hole transport layer and the electron transport layer, respectively, and combining the received holes and electrons, and has high quantum efficiency for fluorescence and phosphorescence may be used as the material of the emission layer according to the present specification. Particular examples of the material of the emission layer comprise 8-hydroxy-quinoline-aluminum complex (Alq₃), carbazole-based compounds, dimerized styryl compounds, BAlq; 10-hydroxybenzoquinoline-metal compounds, benzoxazole-based, benzthiazole-based and benzimidazole-based compounds, poly(p-phenylenevinylene)(PPV)-based polymers, spiro compounds, polyfluorene, rubrene, and the like, but the material of the emission layer is not limited thereto.

A material, which is capable of well receiving electrons injected from the cathode and transferring the injected electrons to the emission layer, and has high mobility for the electrons, is suitable as the material of the electron transport layer according to the present invention. Particular examples of the material of the electron transport layer comprise an 8-hydroxyquinoline Al complex; a complex comprising Alq₃; an organic radical compound; a hydroxyflavone metal complex and the like, but are not limited thereto.

Hereinafter, the present invention will be described in detail with reference to Examples. However, the following Examples are set forth to illustrate the present invention, but do not intend to limit the scope of the present invention.

### EXAMPLE 1

A MoTi layer having a thickness of 30 nm was formed on a glass substrate by a sputtering method by using a MoTi (50:50 at %) alloy target, and a MoTi oxynitride layer having a thickness of 40 nm was formed by a reactive sputtering method by using a MoTi (50:50 at %) target on the MoTi layer. Reflectance of the deposited layer was 9.4%.

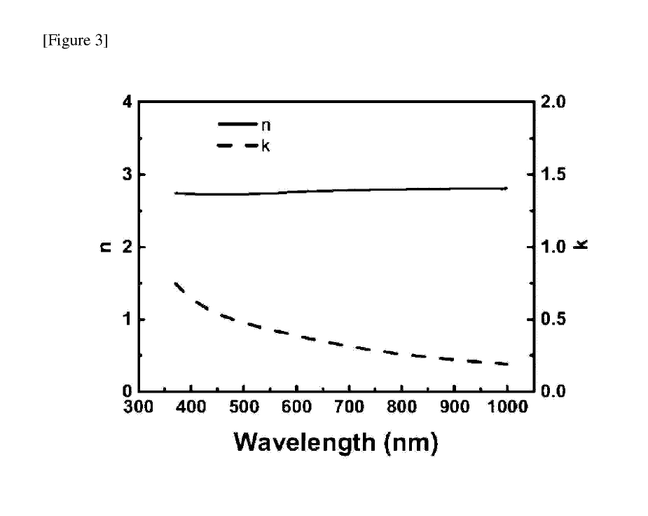

In order to obtain a value of a light absorption coefficient k, a single MoTi oxynitride layer was formed on the glass substrate by the same method as the foregoing method. Then, a refractive index and a light absorption coefficient were measured by using the ellipsometer. Values of n and k at a wavelength of 380 to 1,000 nm are represented in FIG. 3, and a light absorption coefficient value at a wavelength of 550 nm is 0.43. When the light absorption coefficient value was substituted in Equation 1, a value of 0.031 was obtained.

### EXAMPLES 2 TO 12

In the cases of Examples 2 to 12, an optical simulation was performed through the MacLeod program. A value of reflectance in a case where a MoTi oxynitride layer has each thickness was obtained by substituting an optical constant value of Example 1 to the program, and the values are represented in Table 1 below.

TABLE 1

| | Thickness of MoTi | | Reflec- |
|---|---|---|---|
| | oxynitride layer | Value of | tance |
| | (nm) | Equation 1 | (%) |
| Example 2 | 5.5 | 0.0043 | 52 |
| Example 3 | 10 | 0.0078 | 46 |
| Example 4 | 15 | 0.0117 | 39 |
| Example 5 | 20 | 0.0156 | 31 |
| Example 6 | 25 | 0.0195 | 23 |
| Example 7 | 30 | 0.0235 | 18 |
| Example 8 | 35 | 0.0274 | 14 |
| Example 9 | 60 | 0.0469 | 17 |
| Example 10 | 70 | 0.0547 | 23 |
| Example 11 | 80 | 0.0625 | 27 |
| Example 12 | 100 | 0.078 | 31 |

### COMPARATIVE EXAMPLE 1

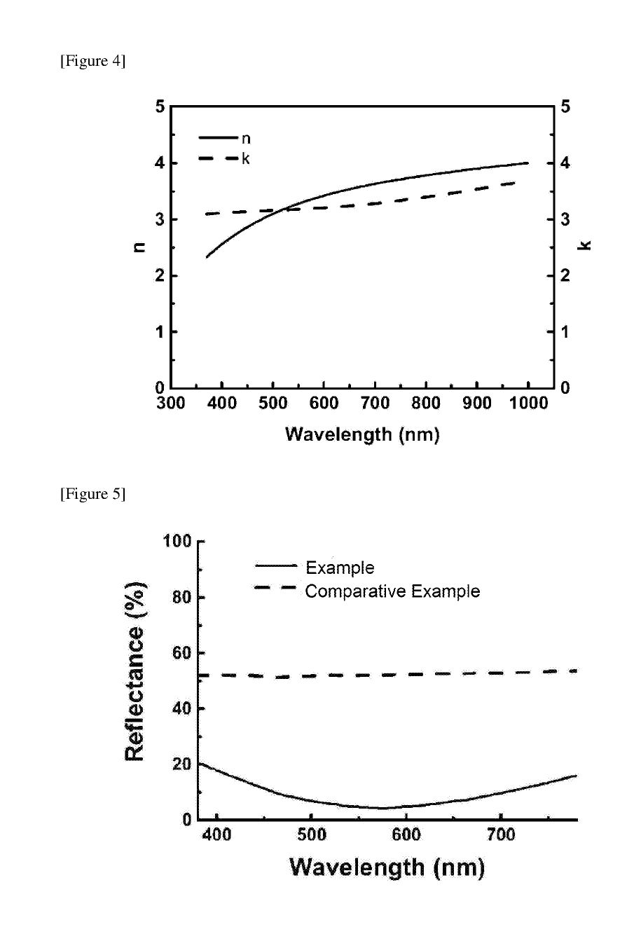

A MoTi layer having a thickness of 30 nm was formed on a glass substrate by a sputtering method by using a MoTi (50:50 at %) alloy target. Reflectance of the deposited layer was 52%. In order to obtain a value of a light absorption coefficient k, a single MoTi layer was formed on the glass substrate by the same method as the foregoing method. Then, a refractive index and a light absorption coefficient were measured by using the ellipsometer. Values of n and k at a wavelength of 380 to 1,000 nm are represented in FIG. 4, and a light absorption coefficient value at a wavelength of 550 nm is 3.18. When the light absorption coefficient value was substituted in Equation 1, a value of 0.23 was obtained. The graph representing a comparison of reflectance of Example 1 and Comparative Example 1 is illustrated in FIG. 5.

### COMPARATIVE EXAMPLE 2

The method was performed in the same manner as that of Example 1 except that a thickness of a MoTi oxynitride layer was 4 nm. A value of Equation 1 was calculated as 0.003. Reflectance was 53%.

### EXAMPLE 13

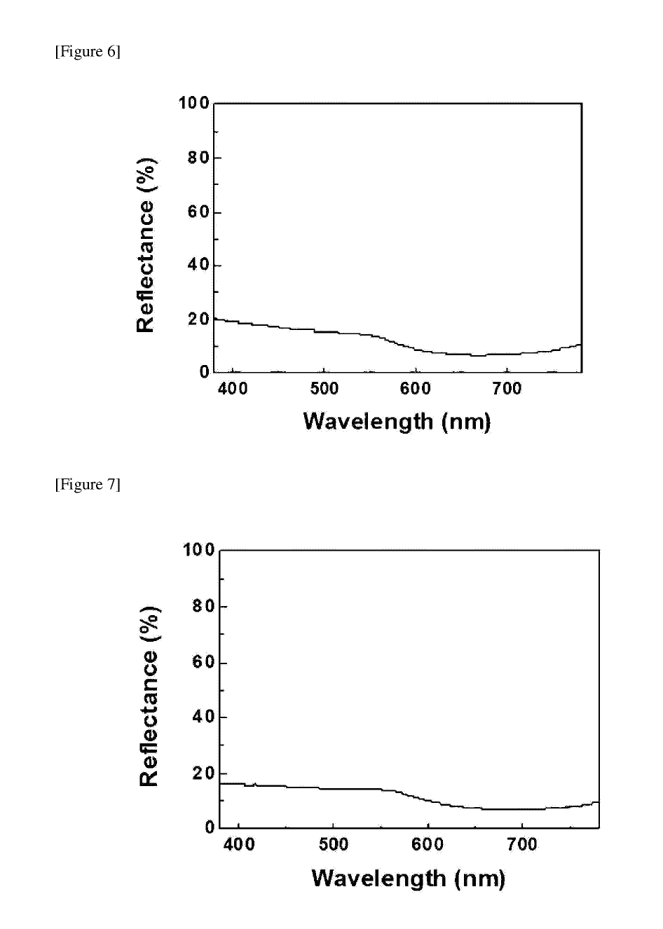

A Cu layer having a thickness of 60 nm was formed as a conductive layer on a glass substrate by a direct current sputtering (DC sputtering) method by using a single Cu target, and a light reflection reducing layer having a thickness of 35 nm and comprising MoTiₐNₓO_{y}(0<a≤2, 0<x≤3, 0<y≤2) was formed by a reactive DC sputtering method by using a MoTi (50:50%) alloy target. Total reflectance according to a wavelength was measured by using Solidspec 3700 (UV-Vis spectrophotometer, Shimadzu Inc.), and a result of the measurement is represented in FIG. 6. A value of Equation 1 of a light reflection reducing layer was 0.059.

### EXAMPLE 14

A Cu layer having a thickness of 60 nm was formed as a first conductive layer on a glass substrate by a DC sputtering method by using a single Cu target, a MoTi layer having a thickness of 20 nm was formed as a second conductive layer by a DC sputtering method by using a MoTi (50:50 at %) alloy target, and a light reflection reducing layer having a thickness of 35 nm and comprising MoTiₐNₓO_{y}(0<a≤2, 0<x≤3, 0<y≤2) was formed by a reactive DC sputtering method by using the same target. Total reflectance according to a wavelength was measured by using Solidspec 3700 (UV-Vis spectrophotometer, Shimadzu Inc.), and a result of the measurement is represented in FIG. 7. A value of Equation 1 of a light reflection reducing layer was 0.059.

### EXAMPLE 15

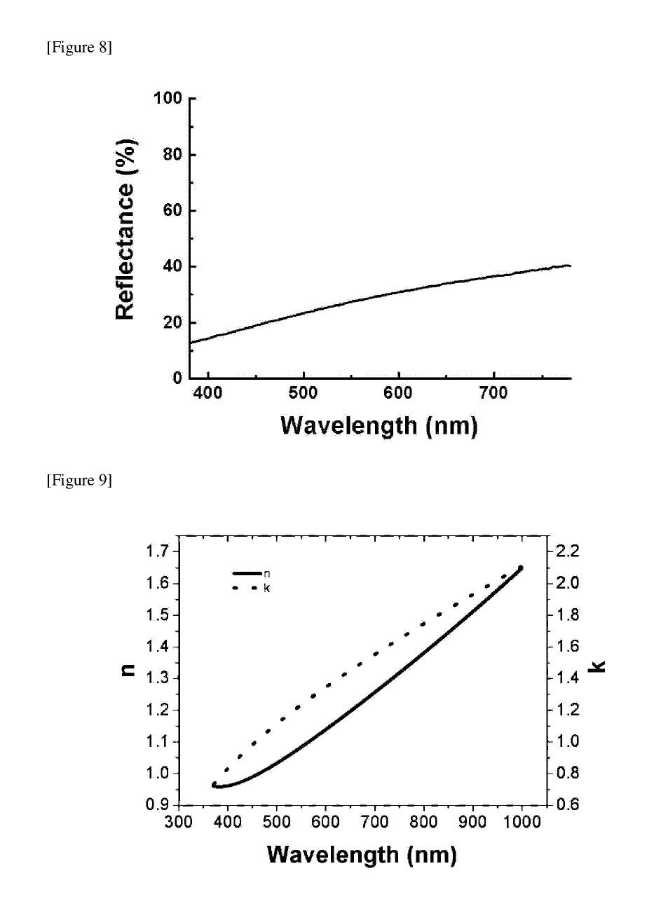

The method was performed in the same manner as that of Example 1 except that a light reflection reducing layer having a thickness of 87 nm was formed by using an Al layer, in which Al was deposited, instead of a MoTi layer, and using an aluminum oxynitride (k=1.24) instead of a MoTi oxynitride. In this case, a value of Equation 1 was 0.2, and reflectance as 28%. FIGS. 8 and 9 represent reflectance and an optical constant value implemented with the present structure.

Through the experiment results of the Examples and the Comparative Examples, it can be seen that the structure described in the claims of the present application exhibits an excellent effect of the light reflection reducing layer.

### EXPLANATION OF REFERENCE NUMERALS AND SYMBOLS

101a, 101b: Gate line

201, 201a, 201b: Data line

301: Thin film transistor

310: Gate electrode

320: Semiconductor layer

330: Source electrode

340: Drain electrode

401: Substrate

510, 520: Organic material layer

601: Second electrode

701: First electrode

801: Light reflection reducing layer

901: Partition wall

1010, 1020: Insulating layer

1. An organic light emitting display device, comprising:
a substrate;
a plurality of gate lines and a plurality of data lines which are provided on the substrate while crossing one another;
a plurality of pixel areas divided by the gate lines and the data lines;
a thin film transistor provided at one side of each of the pixel areas and comprising a gate electrode connected with the gate line, a semiconductor layer provided on the gate electrode while being insulated from the gate electrode, a source electrode electrically connected with the data line, and a drain electrode electrically connected with a pixel electrode or a common electrode;
an organic light emitting device provided on each of the pixel areas and emitting red, green, blue or white light; and
a light reflection reducing layer provided on one surface of at least one of the gate electrode, the source electrode, the drain electrode, the gate line, and the data line,
wherein the light reflection reducing layer satisfies 0.004 or more and 0.22 or less that is a value of Equation 1 below,
$$\frac{( k \times t )}{λ} \qquad [ Equation 1 ]$$
in Equation 1, k means an extinction coefficient of the light reflection reducing layer, t means a thickness of the light reflection reducing layer, and λ means a wavelength of light.

2. The organic light emitting display device of claim 1, wherein a thickness of the light reflection reducing layer is 10 nm or more and 100 nm or less.

3. The organic light emitting display device of claim 1, wherein an extinction coefficient (k) of the light reflection reducing layer is 0.1 or more and 2 or less with light having a wavelength of 550 nm.

4. The organic light emitting display device of claim 1, wherein a refractive index (n) of the light reflection reducing layer is 2 or more and 3 or less with light having a wavelength of 550 nm.

5. The organic light emitting display device of claim 1, wherein light reflectance of an electrode provided with the light reflection reducing layer is 50% or less.

6. The organic light emitting display device of claim 1, wherein the light reflection reducing layer comprises one or more kinds selected from the group consisting of a metal oxide, a metal nitride, and a metal oxynitride.

7. The organic light emitting display device of claim 6, wherein the metal oxide, the metal nitride, and the metal oxynitride are derived from one or two or more metals selected from the group consisting of Cu, Al, Mo, Ti, Ag, Ni, Mn, Au, Cr, and Co.

8. The organic light emitting display device of claim 1, wherein the light reflection reducing layer is provided on a surface facing the substrate of the gate electrode, the source electrode, the drain electrode, the gate line, and the data line.

9. The organic light emitting display device of claim 1, wherein the organic light emitting display device has a bottom emission structure.

10. The organic light emitting display device of claim 1, wherein each of the organic light emitting display devices comprises a first electrode electrically connected with the drain electrode, a second electrode provided while facing the first electrode, and an organic material layer provided between the first electrode and the second electrode and comprising one or more organic light emitting layers.
